(19) United States
(12) Patent Application Publication
(10) Pub. No.: US 2016/0118568 A1
(43) Pub. Date: Apr. 28, 2016

(54) Thermoelectric Element, Assembly and Module, In Particular Intended To Generate An Electric Current In A Motor Vehicle

(71) Applicants: Michel Simonin, Voisins Le Bretonneux (FR); Valeo Systemes Thermiques, Le Mesnil Saint Denis (FR)

(72) Inventors: Cedric De Vaulx, Autouillet (FR); Michel Simonin, Voisins Le Bretonneux (FR)

(21) Appl. No.: 14/884,863

(22) Filed: Oct. 16, 2015

(30) Foreign Application Priority Data
Oct. 24, 2014 (FR) FR 14/60276

(51) Int. Cl. H01L 35/32

(52) U.S. Cl. CPC H01L 35/32

(57) ABSTRACT

The invention relates to a thermoelectric element comprising at least one opening and a set of apertures. The opening is designed to be in a thermal relationship with a hot source, and the apertures are designed to be in a thermal relationship with a cold source that is of a temperature that is lower than that of the hot source. The thermoelectric element is designed to generate an electric current under the action of a temperature gradient applied by the hot source and the cold source between the opening and the apertures. The invention also relates to a thermoelectric module comprising at least one thermoelectric element.

The present invention relates to a thermoelectric element, to an assembly comprising said thermoelectric element and to a thermoelectric module, which are in particular intended to generate an electric current in a motor vehicle.

In the automotive field, thermoelectric modules using elements referred to as thermoelectric elements have already been proposed, making it possible to generate an electric current when a temperature gradient is present between two of their opposing faces in accordance with a phenomenon known as the Seebeck effect.

Such modules are particularly advantageous since they make it possible to produce electricity by converting the heat coming from the exhaust gases of the engine. They thus provide the possibility of reducing the fuel consumption of the vehicle, by replacing, at least in part, the alternator normally provided in said vehicle to generate electricity using a belt driven by the engine crankshaft.

Said modules have a structure in which the hot and cold fluids circulate in tubes which are positioned so as to be in contact with thermoelectric elements, such that a temperature gradient is established between the opposing faces of the thermoelectric element, thus generating an electric current in the module. Taking into account the flow cross sections available for the fluids, the known modules are of a size that is far greater than that of the thermoelectric elements alone.

The invention proposes improving the situation, and to this end relates to a thermoelectric element comprising at least one opening and a set of apertures, the opening being designed to be in a thermal relationship with a hot source and the apertures being designed to be in a thermal relationship with a cold source that is of a temperature that is lower than that of the hot source, said thermoelectric element being designed to generate an electric current under the action of a temperature gradient applied by the hot source and the cold source between the opening and the apertures.

The thermoelectric element according to the invention is designed, owing to the opening and the apertures thereof, to receive circuits therein which allow heat exchange with the cold and hot sources. The thermoelectric element thus allows an integrated assembly to be formed together with the circuits, and this also facilitates pre-assembly of the thermoelectric modules with which said element is equipped.

According to different embodiments of the invention, which may be taken together or separately:
the opening is a through-opening and the apertures are through-apertures;
the opening and the apertures each have an opening cross section having a closed contour,
said opening cross section of the opening is larger than the total of the opening cross sections of each of the apertures;
the opening and the apertures are circular;
the thermoelectric element is cylindrical;
the thermoelectric element is ovoid;
the apertures are positioned around the opening;
the opening is centred relative to a periphery of the thermoelectric element;
the apertures are distributed over a periphery of the thermoelectric element;
the apertures are distributed regularly around the opening;
the hot source is a hot fluid;
the cold source is a cold fluid.

The invention also relates to an assembly comprising a thermoelectric element as defined above, and two circuits for circulating a hot fluid from the hot source, referred to as first and second circuits, the first circuit being in contact with the thermoelectric element and the second circuit being positioned within the first circuit.

Therefore, owing to the invention, it is possible to direct more or less hot fluid towards the first and/or the second circuit, such that the thermoelectric element integrates a diversion function, referred to as a bypass function, into the overall size thereof, allowing the hot fluid circulating in the thermoelectric module comprising such an assembly to exchange more or less heat with the thermoelectric element.

According to one embodiment of the invention, the first circuit comprises a first tube and the second circuit comprises a second tube, the second tube being positioned within the first tube.

According to one aspect of the invention, the assembly comprises turbulators which are in contact with the first and the second tubes.

The invention also relates to a thermoelectric module comprising at least one thermoelectric element as defined above.

According to one embodiment of the invention, said thermoelectric module comprises tubing for circulating a cold fluid from the cold source, which tubing is in a heat-exchange relationship with each of the apertures.

According to one aspect of the invention, said thermoelectric module comprises two circuits for circulating a hot fluid from the hot source, referred to as first and second circuits, the first circuit being in contact with the thermoelectric element and the second circuit being positioned within the first circuit.

Advantageously, the first circuit comprises a first tube and the second circuit comprises a second tube, the second tube being positioned within the first tube.

Advantageously, the thermoelectric module comprises a bypass valve which is designed to distribute the hot fluid between the first and the second circuit.

According to one aspect of the invention, the thermoelectric elements are stacked in a stacking direction such that each of the openings and each of the apertures are respectively arranged so as to be facing one another.

The invention will be better understood in the light of the following description, which is given only by way of indication and is not intended to having a limiting effect, together with the accompanying drawings, in which:

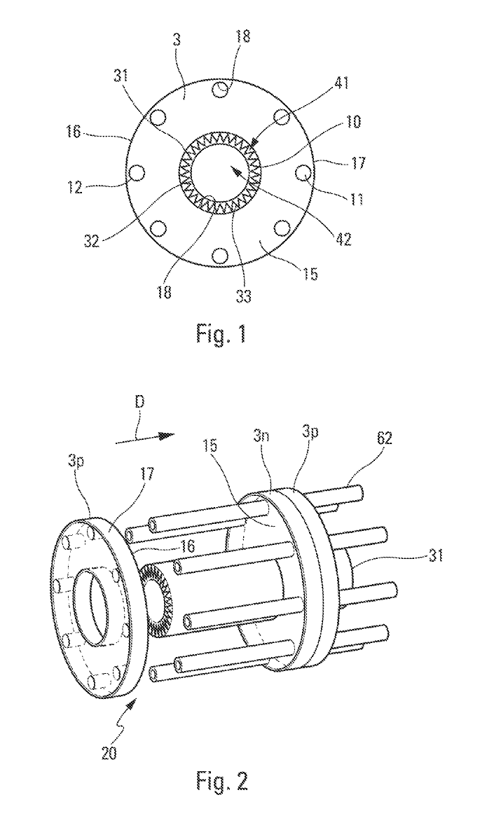

FIG. 1 is a schematic front view of an embodiment of an assembly comprising a thermoelectric element according to the invention;

FIG. 2 is a perspective exploded view of the components of a thermoelectric module according to the invention during assembly;

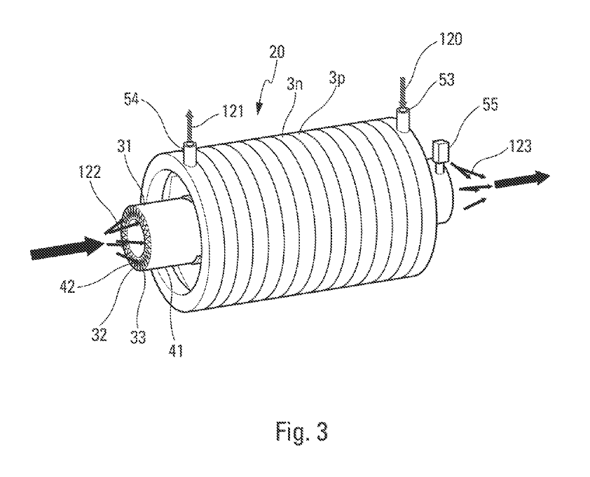

FIG. 3 is a perspective view of an embodiment of a thermoelectric module according to the invention.

An assembly according to the invention is shown in FIG. 1. Such an assembly comprises a thermoelectric element 3 which is capable of making use of the temperature difference between a first fluid, referred to as a hot fluid, in particular exhaust gases from an engine, and a second fluid, referred to as a cold fluid, in particular a coolant liquid in a cooling circuit, of a temperature that is lower than that of the first fluid. The second fluid therefore has a heat-exchange coefficient that is higher than said first fluid in this case.

According to the invention, the thermoelectric element 3 comprises at least one opening 10 and a set of apertures 11, 12, in this case eight apertures 11, 12. The opening 10 is designed to be in a thermal relationship with the hot fluid and the apertures 11, 12 are designed to be in a thermal relationship with the cold fluid. The thermoelectric element 3 is designed to generate an electric current under the action of a temperature gradient applied by the hot source and the cold source between the opening 10 and the apertures 11, 12.

The assembly further comprises two circuits 41, 42 for circulating the hot fluid from the hot source, which circuits are independent of each other and are referred to as first 41 and second 42 circuits, the first circuit 41 being in contact with the thermoelectric element 3 and the second circuit 42 being positioned within the first circuit 41. The first circuit 41 comprises a first tube 31 and the second circuit 42 comprises a second tube 32, the second tube 32 being positioned within the first tube 31. The assembly comprises turbulators 33 which are in contact with the first 31 and the second 32 tubes and in particular allow the heat exchange between the hot fluid and the first tube 31 to be improved.

The second circuit 42 provides the module according to the invention with a bypass function, while remaining within the thermoelectric element. In this way, it is possible for the hot fluid to exchange the maximum amount of heat with the thermoelectric element by passing through the first circuit, or to exchange less heat by passing through the second circuit. It is therefore not necessary to provide the thermoelectric module comprising such thermoelectric elements with an additional external circuit in order to produce this bypass function.

Such elements function, according to the Seebeck effect, by allowing an electric current to be generated in a load connected between the opening 10 and the apertures 11, 12 which are subjected to the temperature gradient.

In this case, the opening 10 is a through-opening and the apertures 11, 12 are through-apertures, such that they can receive tubing for circulating fluid in addition to the tubes 31, 32, as will be seen in the remainder of the description. The opening 10 and the apertures 11, 12 advantageously have a closed contour, in particular a circular contour. They define inner faces 18 of the thermoelectric element 3 with which the heat exchange takes place, and they are the active faces of the thermoelectric element. Here, it is understood that the heat exchange between the hot fluid and the thermoelectric element 3 takes place in the region of the inner face 18 of the opening 10 and the heat exchange between the cold fluid and the thermoelectric element 3 takes place in the region of the inner face 18 of the apertures 11, 12. The temperature gradient allowing the thermoelectric element 3 to generate an electric current is therefore produced between the inner face 18 of the opening 10 and the inner face 18 of the apertures 11, 12.

In the embodiment of the thermoelectric element 3 shown in FIG. 1, the thermoelectric element 3 is cylindrical and circular. According to an embodiment that is not shown, the thermoelectric element is ovoid. Said element comprises a first and a second large planar face 15, 16, which are in parallel and in which the opening 10 and the apertures 11, 12 are located. When the opening 10 is a through-opening and the apertures 11, 12 are through-apertures, they pass through the thermoelectric element 3 from the first large planar face thereof to the second large planar face thereof. The thermoelectric element 3 also comprises a lateral face 17, which defines the thickness of the thermoelectric element 3. In other words, the lateral face 17 defines a periphery of the thermoelectric element 3 that interconnects the two large planar faces 15, 16. The lateral face 17 is therefore circular in this case.

The opening 10 and the apertures 11, 12 each have an opening cross section. The opening cross sections of each of the apertures 11, 12 are identical, for example. The opening cross section of the opening 10 is in particular larger than each of the opening cross sections of the apertures 11, 12, and is in particular larger than the total of each of the opening cross sections of the apertures 11, 12. In this way, exchange is promoted between the thermoelectric elements 3 and the fluid having the lowest heat-exchange coefficient, that is to say the hot fluid, in this case the exhaust gases.

In this case, the opening 10 is centred relative to a periphery of the thermoelectric element 3. The apertures 11, 12 are in particular distributed over the periphery of the thermoelectric element. In this case, they are located around the opening 10, and in particular regularly around the opening 10.

As shown in FIGS. 2 and 3, the invention also relates to a thermoelectric module 20 comprising a plurality of thermoelectric elements 3 as described above.

In this case, the thermoelectric elements 3 are stacked in a stacking direction D such that each of the openings 10 and each of the apertures 11, 12 are arranged so as to be facing one another. In other words, the openings 10 are mutually coaxial and the apertures 11, 12 are mutually coaxial. The thermoelectric elements 3 are positioned such that the first large face 15 of a thermoelectric element is facing the second large face 16 of an adjacent thermoelectric element, and vice versa.

The thermoelectric elements may firstly be elements 3p of a first type, referred to as the P-type, for establishing a difference in electrical potential in a so-called positive direction when they are subjected to a given temperature gradient, and the rest of them may be elements 3n of a second type, referred to as the N-type, for producing a difference in electrical potential in the opposite, so-called negative, direction when they are subjected to the same temperature gradient.

In a manner known to a person skilled in the art, such thermoelectric elements are formed, for example, by tellurides of general formula (Bi,Sb)2Te3 for the N-type and Bi1-xSbxTe3 for the P-type, or by silicides of general formula Mg2(Si,Ge)xSn1-x for the N-type and MnSix for the P-type, or by skutterudites of general formula CoSb3 for the N-type and FeSb3 for the P-type.

Said thermoelectric elements 3 are arranged such that the P-type thermoelectric elements alternate with the N-type thermoelectric elements in the stacking direction D of the thermoelectric elements. They have in particular identical shapes and dimensions. They may, however, have a thickness, that is to say a dimension between their two large faces, which is different from one type to the other, in particular according to their electrical conductivity.

Said thermoelectric elements 3 are, for example, grouped in pairs, each pair being formed by one P-type thermoelectric element and one N-type thermoelectric element, and said module 20 is designed to allow current to circulate between the thermoelectric elements in the same pair and to allow current to circulate between the neighbouring thermoelectric elements belonging to adjacent pairs. In this way, circulation in series of the electric current between the thermoelectric elements 3 which are arranged alongside one another in the stacking direction D is provided.

The thermoelectric module 20 comprises tubing 62 for circulating fluid in a fluid exchange relationship with the apertures 11, 12. This is therefore tubing for circulating cold fluid. In this case, said tubing 62 passes through the apertures 11, 12. Therefore, once the tubing 62 is mounted in the thermoelectric elements by means of the apertures 11, 12, it forms a pre-assembled structure together with the thermoelectric elements, making it easier to rigidly connect the thermoelectric elements to the tubing.

In order to rigidly connect the thermoelectric elements to the tubing and to minimise the temperature resistance therebetween, it is possible to rigidly connect said elements and tubing by soldering, by inflating the tubes and tubing or by simple bonding. In other words, the tubes 31, 32 and the tubing 62 are for example soldered to the thermoelectric elements 3 of the thermoelectric module 20. According to a variant of the invention, they are expanded in the thermoelectric elements 3 of the thermoelectric module 20. According to another variant of the invention, they are bonded to the thermoelectric elements 3 of the thermoelectric module 20.

Once assembled, the module as shown in FIG. 3 further comprises an inlet collector box 53 for the cold fluid that is intended to guide the cold fluid within the tubing and an outlet collector box 54 for the cold fluid that guides the cold fluid to the outside of the thermoelectric module after it has passed through the thermoelectric modules 20. The cold fluid enters the inlet collector box 53 in the direction provided with reference numeral 120 and leaves the outlet collector box 54 in the direction provided with reference numeral 121. It may be noted that, owing to the invention, the thermoelectric elements 3 and the tubes 31, 32 or tubing 62 are held together independently of the presence of the inlet collector box 53 and outlet collector box 54.

The thermoelectric module comprises a bypass valve 55 which is designed to distribute the hot fluid between the first 41 and the second 42 circuit. Said valve allows the exhaust gases to be distributed when the temperature is too high and/or when the head loss is too great.

In the embodiment shown in FIG. 3, the bypass valve 55 is closed, that is to say all the hot fluid is directed into the first circuit 41 in the directions provided with reference numeral 122, passes through the thermoelectric module and leaves said module in the directions provided with reference numeral 123.

When the bypass valve 55 is open, the hot fluid is distributed between the first 41 and the second 42 circuit, that is to say into the first tube 31 and the second tube 32.

1. A thermoelectric element comprising at least one opening and a set of apertures, wherein the opening is designed to be in a thermal relationship with a hot source, and the apertures are designed to be in a thermal relationship with a cold source that is of a temperature that is lower than that of the hot source, and wherein the thermoelectric element is designed to generate an electric current under the action of a temperature gradient applied by the hot source and the cold source between the opening and the apertures.

2. The thermoelectric element according to claim 1, wherein the opening is a through-opening and the apertures are through-apertures.

3. The thermoelectric element according to claim 1, wherein the opening and the apertures each have an opening cross section having a closed contour, wherein the opening cross section of the opening is larger than the total of the opening cross sections of each of the apertures.

4. The thermoelectric element according to claim 1, wherein the opening and the apertures are circular.

5. The thermoelectric element according to claim 1, wherein the thermoelectric element is cylindrical.

6. The thermoelectric element according to claim 1, wherein the apertures are positioned around the opening.

7. The thermoelectric element according to claim 6, wherein the apertures are distributed regularly around the opening.

8. The thermoelectric element according to claim 1, wherein the opening is centered relative to a periphery of the thermoelectric element.

9. The thermoelectric element according to claim 1, wherein the apertures are distributed over a periphery of the thermoelectric element.

10. A thermoelectric module comprising at least one thermoelectric element according to claim 1.

11. The thermoelectric module according to claim 10, comprising tubing for circulating a cold fluid from the cold source, which tubing is in a heat-exchange relationship with each of the apertures.

12. The thermoelectric module according to claim 10, comprising first and second circuits for circulating a hot fluid from the hot source, the first circuit being in contact with the thermoelectric element and the second circuit being positioned within the first circuit.

13. The thermoelectric module according to claim 12, wherein the first circuit comprises a first tube and the second circuit comprises a second tube, and wherein the second tube is positioned within the first tube.

14. The thermoelectric module according to claim 12, wherein the thermoelectric module comprising a bypass valve which is designed to distribute the hot fluid between the first and the second circuit.

15. The thermoelectric module according to claim 10, wherein the thermoelectric elements are stacked in a stacking direction such that each of the openings and each of the apertures are respectively arranged so as to be facing one another.

16. The thermoelectric element according to claim 2, wherein the opening and the apertures each have an opening cross section having a closed contour, wherein the opening cross section of the opening is larger than the total of the opening cross sections of each of the apertures.

17. The thermoelectric module according to claim 11, comprising first and second circuits for circulating a hot fluid from the hot source, the first circuit being in contact with the thermoelectric element and the second circuit being positioned within the first circuit.
